(19) United States
(12) Patent Application Publication
(10) Pub. No.: US 2026/0322109 A1
(43) Pub. Date: Oct. 15, 2026

(54) Marine DC Solid-State Circuit Breaker Arrangement

(71) Applicant: Zhejiang Hele Tonghai Technology Co., Ltd., Taizhou (CN)

(72) Inventor: Changle Li, Taizhou (CN)

(21) Appl. No.: 19/330,841

(22) Filed: Sep. 17, 2025

(30) Foreign Application Priority Data
Apr. 10, 2025 (CN) 202510446979.3

(51) Int. Cl. H02H 7/26; G01R 31/00; G01R 31/08; G01R 31/52; H02H 1/00; H02H 7/22

(52) U.S. Cl. CPC H02H 7/268; G01R 31/008; G01R 31/086; G01R 31/52; H02H 1/0007; H02H 7/22

(57) ABSTRACT

A marine DC solid-state circuit breaker arrangement includes a controller, two signal acquisition modules, a main switch and a bus circuit comprising a port circuit and a starboard circuit, wherein the main switch comprises a port switch and a starboard switch, wherein the marine DC solid-state circuit breaker arrangement further includes a first freewheeling circuit and a second freewheeling circuit, wherein the port switch and the first freewheeling circuit, together with the starboard switch and the second freewheeling circuit, form two buck circuits connected in the marine DC solid-state circuit breaker arrangement in an anti-series manner.

### CROSS REFERENCE OF RELATED APPLICATION

This application is a non-provisional application that claims priority under 35U.S.C. § 119 to China application number CN202510446979.3, filing date Apr. 10, 2025, wherein the entire content of which is expressly incorporated herein by reference.

### BACKGROUND OF THE PRESENT INVENTION

### Field of Invention

The present invention relates to field of direct current technology, and more particularly to a marine direct current solid-state circuit breaker arrangement.

### Description of Related Arts

The DC system responds very quickly to current changes and can quickly reflect the actual state of the current. It has been widely used in many fields such as power systems, industrial automation, and scientific research. Especially in ship integrated power systems, DC power has been increasingly used due to its advantages such as high efficiency and good performance.

However, the main problem with DC systems is that they have no natural zero crossing, the impedance of DC lines is low, and DC equipment is sensitive to overcurrent (or overvoltage). Therefore, how to quickly detect circuit faults and quickly and accurately cut off the faults is a key factor in the adaptability of DC systems to ship systems.

DC systems respond very quickly to current changes, quickly reflecting the actual current state. This is particularly important for control systems requiring fast response times. DC systems can accurately measure a wide range of currents, from milliamperes to hundreds of kiloamperes, meeting the needs of diverse application scenarios. DC systems typically offer excellent isolation, enabling safe measurements in high-voltage and high-current environments, effectively protecting measurement equipment and personnel. Due to their numerous advantages, DC systems have been widely adopted in various fields, including power systems, industrial automation, and scientific research. In particular, DC power systems are increasingly being used in integrated shipboard power systems due to their high efficiency and performance. However, key challenges with DC systems are the lack of a natural zero crossing, the low impedance of DC lines, and the increased sensitivity of DC equipment to overcurrent (or overvoltage). Consequently, DC system protection design presents more challenges than AC systems. Taking a ship's DC system as an example, when a short-circuit fault occurs in the DC system, the current rise rate can reach over 20 A/μs, and the peak current can reach over 110 kA, making disconnection difficult. If a traditional mechanical circuit breaker is used for protection, specially designed disconnection, arc extinguishing, and contact systems are required to achieve protection. In addition, the large amount of energy stored in the line inductance needs to be released, which will increase the system's withstand voltage and insulation strength.

Depending on the operating conditions, potential protective devices include circuit breakers, fuses, load switches, disconnectors, and converters. Load switches and disconnectors do not provide short-circuit protection; DC fuses only provide short-circuit protection, but they have long tripping times and are difficult to maintain. If the converter's power electronics are used for protection, the load-side circuit breaker can be replaced with a DC disconnector. However, in the event of a converter fault or current limiting failure, backup short-circuit protection is still required between the upstream power supply and the converter. The design of shipboard DC power system protection presents the challenge of traditional fault detection and protection technologies based on conventional circuit breakers being no longer applicable. On the low-voltage DC side of the ship's integrated power system, DC circuit breakers are required as fault protection devices for downstream inverters. These devices must operate within milliseconds. Failure to quickly trip the system will cause a sudden increase in system fault current and a drop in DC bus voltage, impacting the reliable operation of other load devices on the bus. As shown in FIG. 1, if the input side of the subsequent converter is short-circuited, the converter fails, or the current limiting fails, that is, fault F1 or F2 in FIG. 1 occurs, if the fault cannot be quickly and reliably disconnected, it will cause the system fault current to surge and the DC bus voltage to drop, causing other normally operating converters to shut down for protection, seriously affecting the continuity and reliability of power supply.

In addition, the DC side of the converter is equipped with parallel capacitors for energy storage and wave smoothing, as shown in FIGS. 2 and 3. When a short circuit occurs, the energy stored in the capacitors will be rapidly released to the short circuit point, and the discharge current can range from thousands of amperes to tens of thousands of amperes. As a result, the energy stored in the capacitors and the parallel-connected capacitors used for energy storage and wave smoothing will be rapidly released to the short circuit point when a short circuit occurs. The released current can reach thousands of amperes to tens of thousands of amperes, causing damage to the capacitors or other equipment and increasing the current intensity at the fault point. In the event of a short circuit, if the DC bus voltage drop is to be maintained within the normal range, the fault must be quickly cleared within a few milliseconds to maintain the DC bus voltage drop within the normal range and allow other equipment on the bus to operate normally. This places high demands on the speed of the DC circuit breaker.

### SUMMARY OF THE PRESENT INVENTION

The invention is advantageous in that it provides a marine DC solid-state circuit breaker arrangement. The disconnecting circuit can accurately determine the fault location in a bus circuit in a short time and quickly disconnect the fault circuit, thereby ensuring the safety and stability of the bus circuit.

The present invention provides a marine DC solid-state circuit breaker arrangement comprising a controller, two signal acquisition modules, a main switch, and a bus circuit; wherein the bus circuit comprises a port circuit and a starboard circuit; the main switch comprises a port switch and a starboard switch, wherein the output end of the port switch is connected to the output end of the starboard switch, the input end of the port switch is connected to the port circuit, and the input end of the starboard switch is connected to the starboard circuit; the two signal acquisition modules are connected to the bus circuit and are used to detect electrical signals in the bus circuit and send the electrical signals to the controller; one end of the controller is connected to the main switch and the other end is connected to the two signal acquisition modules; the controller determines a fault location in the bus circuit based on the electrical signals sent by the signal acquisition modules, and controls the port switch and the starboard switch to close and open according to the fault location.

According to one embodiment of the present invention, the port switch comprises a first IGBT module and a second IGBT module, the collector of the first IGBT module is connected to the collector of the second IGBT module and is connected to the bus circuit, and the emitter of the first IGBT module is connected to the emitter of the second IGBT module as the output end of the port switch;

The starboard switch comprises a third IGBT module and a fourth IGBT module. The collector of the third IGBT module is connected to the collector of the fourth IGBT module and is also connected to the bus circuit. The emitter of the third IGBT module is connected to the emitter of the fourth IGBT module as the output end of the starboard switch.

According to one embodiment of the present invention, the marine DC solid-state circuit breaker arrangement further comprises a first freewheeling circuit and a second freewheeling circuit; the first freewheeling circuit comprises a first power diode and a first capacitor, the cathode of the first power diode is connected to the output end of the port switch, the anode of the first power diode is connected to the negative electrode of the port circuit, and the first capacitor is connected in parallel between the positive and negative electrodes of the port circuit; the second freewheeling circuit comprises a second power diode and a second capacitor, the cathode of the second power diode is connected to the output end of the starboard switch, the anode of the second power diode is connected to the negative electrode of the starboard circuit, and the second capacitor is connected in parallel between the positive and negative electrodes of the starboard circuit. The port switch and the first freewheeling circuit and the starboard switch and the second freewheeling circuit form two step-down circuits connected in anti-series to the marine DC solid-state breaking arrangement.

According to one embodiment of the present invention, the device further comprises a current-limiting reactor connected between the port switch and the starboard switch.

According to one embodiment of the present invention, an IGBT driver board is further included. The IGBT driver board is connected between the main switch and the controller and is used to control the main switch according to a control instruction sent by the controller.

According to one embodiment of the present invention, the two signal acquisition modules comprise a port signal acquisition module and a starboard signal acquisition module; the controller is configured to compare the port electrical signal acquired by the port signal acquisition module and the starboard electrical signal acquired by the starboard signal acquisition module with the normal electrical signal, and control the port switch to be disconnected and/or the starboard switch to be disconnected when the fault location is determined.

According to one embodiment of the present invention, the port electrical signal is a port current, and the starboard electrical signal is a starboard current; the controller is configured to, when determining that a current rise rate of the port current is greater than a rise rate threshold, determine that the fault location occurs on the port side of the bus circuit, and control the port switch to disconnect; and, when determining that a current rise rate of the starboard current is greater than the rise rate threshold, determine that the fault location occurs on the starboard side of the bus circuit, and control the starboard switch to disconnect.

According to one embodiment of the present invention, the controller is further configured to, when it is determined that the current amplitude of the port current is greater than a current threshold, determine that the fault location occurs on the port side of the bus circuit, and the controller controls the port switch to disconnect; and, when it is determined that the current amplitude of the starboard current is greater than the current threshold, determine that the fault location occurs on the starboard side of the bus circuit, and the controller controls the starboard switch to disconnect.

According to one embodiment of the present invention, each of the two signal acquisition modules is a Rogowski coil.

According to one embodiment of the present invention, the port electrical signal is a port voltage, and the starboard electrical signal is a starboard voltage; and the controller is configured to control the port switch and the starboard switch to be disconnected when it is determined that the difference between the port voltage and the starboard voltage is greater than a voltage difference threshold.

The present invention is advantageous in that the controller detects electrical signals in real time through the signal acquisition modules. Once a line fault is detected, the port switch or the starboard switch can be quickly cut off according to the fault location to accurately cut off the fault circuit, avoid burning of electrical appliances connected to the bus circuit, and improve the stability and safety of the bus circuit.

### BRIEF DESCRIPTION OF THE DRAWINGS

FIG. 1 is a structural diagram of a conventional DC regional power distribution system;

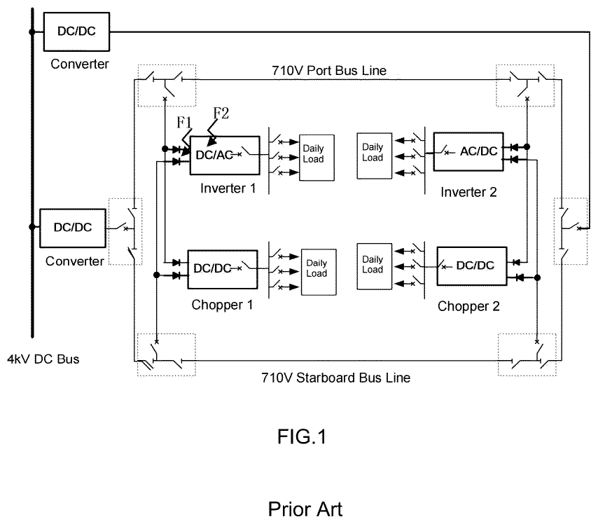

FIG. 2 is a schematic diagram of a conventional short circuit on the input side of the converter;

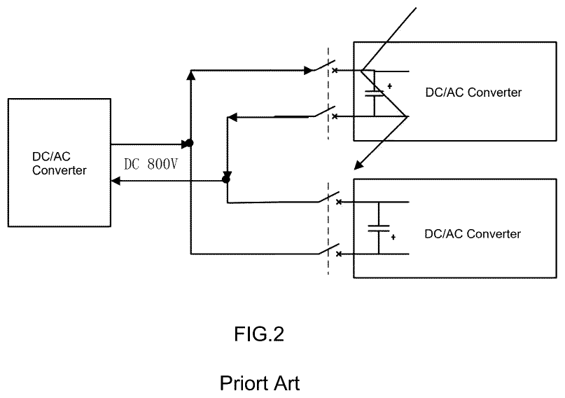

FIG. 3 shows the conventional short-circuit current waveform under rated operating conditions;

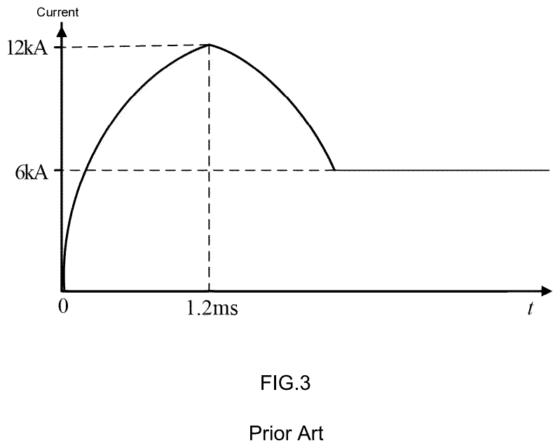

FIG. 4 is a schematic structural diagram of a marine DC solid-state circuit breaker arrangement according to an embodiment of the present application;

FIG. 5 is a schematic structural diagram of a main switch according to an embodiment of the present application;

FIG. 6 is a schematic structural diagram of another alternative marine DC solid-state circuit breaker arrangement according to the embodiment of the present application;

FIG. 7 is a schematic structural diagram of another alternative marine DC solid-state circuit breaker arrangement according to the embodiment of the present application;

FIG. 8 is a schematic structural diagram of a signal acquisition module according to the embodiment of the present application;

FIG. 9 is a schematic diagram of a control flow of the main controller according to the embodiment of the present application;

FIG. 10 is a schematic structural diagram of another alternative signal acquisition module according to the embodiment of the present application;

FIG. 11 is a schematic structural diagram of another alternative signal acquisition module according to the embodiment of the present application;

FIG. 12 is a schematic diagram of a short-circuit protection simulation.

### DETAILED DESCRIPTION OF THE PREFERRED EMBODIMENT

The terms and words used in the following description are not limited to the literal meanings, but are merely used by the inventor to enable a clear and consistent understanding of the present invention. Therefore, it will be apparent to those skilled in the art that the following description of various embodiments of the present invention is provided for illustration purposes only and not for the purpose of limiting the present invention as defined by the appended claims and their equivalents.

Although ordinal numbers such as “first,” “second,” and the like will be used to describe various components, these are not intended to limit those components. The terms are used solely to distinguish one component from another. For example, a first component could be referred to as a second component, and similarly, a second component could be referred to as a first component without departing from the teachings of the present inventive concept. As used herein, the term “and/or” comprises any and all combinations of one or more of the associated listed items.

The terms used herein are for the purpose of describing various embodiments only and are not intended to be limiting. As used herein, the singular is intended to include the plural, unless the context clearly indicates otherwise. It will also be understood that the terms “comprising” and/or “having” when used in this specification specify the presence of a stated feature, number, step, operation, component, element, or combination thereof, and do not preclude the presence or addition of one or more other features, numbers, steps, operations, components, elements, or groups thereof.

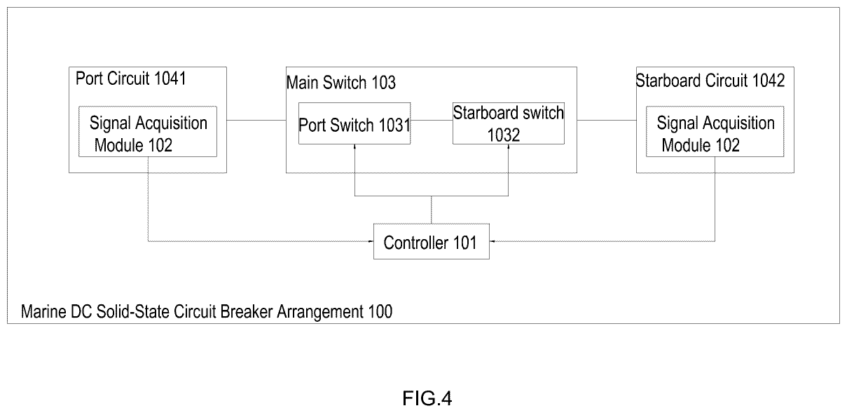

As shown in FIG. 4, a structural diagram of a marine DC solid-state circuit breaker arrangement according to an embodiment of the present application is shown. The marine DC solid-state circuit breaker arrangement comprises a controller 101, a signal acquisition module 102, a main switch 103, and a bus circuit; wherein the main switch 103 comprises a port switch 1031 and a starboard switch 1032, the output end of the port switch 1031 is connected to the output end of the starboard switch 1032, the bus circuit comprises a port circuit 1041 and a starboard circuit 1042, the input end of the port switch 1031 is connected to the port circuit 1041, the input end of the starboard switch 1032 is connected to the starboard circuit 1042. The signal acquisition module 102 is connected to the bus circuit, and is used to detect the electrical signal of the bus circuit and send the electrical signal to the controller 101. One end of the controller 101 is connected to the main switch 103, and the other end is connected to the signal acquisition module 102. The controller 101 determines the fault location in the bus circuit based on the electrical signal sent by the signal acquisition module 102, and controls the opening and closing of the port switch 1031 and the starboard switch 1032 according to the fault location.

During operation, the controller 101 monitors the electrical signals of port circuit 1041 and starboard circuit 1042 in the bus circuit in real time. These signals can reflect the bus circuit's operating status, fault conditions, or conditions requiring circuit breaker disconnection in real time. When the controller 101 detects a condition requiring circuit disconnection, such as overcurrent, overvoltage, short circuit, open circuit, or other fault in the bus circuit, it determines whether the electrical signal is occurring in the port circuit 1041 or the starboard circuit 1042, and disconnects the corresponding port switch 1031 or the starboard switch 1032 based on the location. Conversely, once the fault is resolved and the electrical signals of the port circuit 1041 and the starboard circuit 1042 meet normal conditions, the controller 101 can also send a restoration signal to close the main switch 103, restoring circuit access.

Under normal operating conditions, the main switch 103 is in a closed state, and current can flow in both directions. The controller 101 can be set locally and directly connected to the main switch. The controller 101 can also remotely control the main switch. Through the shutdown command issued by the controller 101, the port switch 1031 and/or the starboard switch 1032 are turned off, accurately determining the circuit status and fault location, and quickly separating the faulty part from the normal part. Compared with conventional protective electrical appliances, such as circuit breakers, fuses, load switches, disconnectors and converters, it can effectively improve the precise control of circuit faults and quickly cut off the circuit, avoiding the burning of electrical appliances connected to the bus circuit, and improving the stability and safety of the bus circuit.

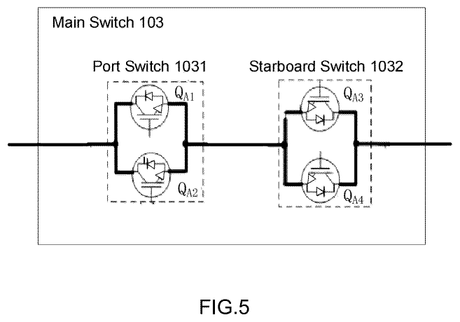

As shown in FIG. 5, a schematic diagram of the structure of the main switch 103 according to the embodiment of the present application is shown, wherein the port switch 1031 comprises a first IGBT module Q_{A1} and a second IGBT module Q_{A2}, wherein the collector of the first IGBT module Q_{A1} and the collector of the second IGBT module Q_{A2} are connected and connected to the bus circuit, and the emitter of the first IGBT module Q_{A1} and the emitter of the second IGBT module Q_{A2} are connected as the output end of the port switch. The starboard switch 1032 comprises a third IGBT module Q_{A3} and a fourth IGBT module Q_{A4}, wherein the collector of the third IGBT module Q_{A3} and the collector of the fourth IGBT module Q_{A4} are connected and connected to the bus circuit; the emitter of the third IGBT module Q_{A3} and the emitter of the fourth IGBT module Q_{A4} are connected as the output end of the starboard switch 1032.

When the electric current flows from the port side to the starboard side, the voltage of the port circuit 1041 is higher than that of the starboard circuit 1042. The controller 101 turns on the IGBTs in the port switch 1031 and the starboard switch 1032. The current flows through the port circuit 1041, Q_{A1}, Q_{A4}, and the starboard circuit 1042 in sequence. If the IGBT is not turned on, the anti-parallel diode inside the IGBT module will turn on to provide a path, and the current path is that the current flows through the port circuit 1041, the anti-parallel diode within Q_{A1}, the anti-parallel diode within Q_{A4}, and the starboard circuit 1042 in sequence.

When the electric current flows from starboard to port, the voltage of starboard circuit 1042 is higher than that of port circuit 1041, and the controller 101 causes the IGBTs in starboard and port switches 1032 and 1031 to conduct forward. The current flows sequentially through starboard circuit 1042, Q_{A3,} Q_{A2}, and the port circuit 1041. If the IGBTs are not conducting, the antiparallel diodes within the IGBT module conduct, providing a path for the current to flow. The current then flows sequentially through the starboard circuit 1042, the anti-parallel diode within Q_{A3}, the anti-parallel diode within Q_{A2}, and finally the port circuit 1041.

The circuit breaker arrangement of this embodiment utilizes two parallel IGBT modules (Q_{A1}-Q_{A4}) as the main switch. These modules are then connected in anti-series to form the main disconnect circuit switch. Because IGBTs are used as the main switches, the disconnect circuit exhibits extremely fast response speeds, enabling the circuit to be switched on and off in a very short time.

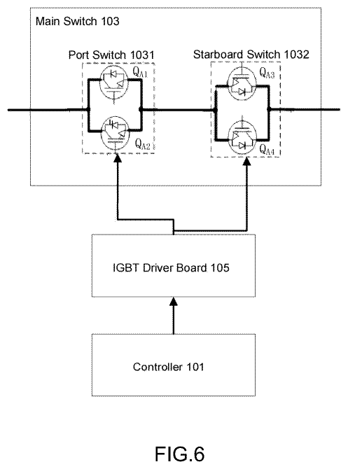

As shown in FIG. 6, to improve the stability of the disconnect circuit, an IGBT driver board 105 is included between the main switch 103 and the controller 101. Connected between the main switch 103 and the controller 101, the IGBT driver board 105 controls the main switch 103 according to control instructions from the controller 101. Because both the IGBT driver board 105 and the IGBT main switch 103 are designed with high reliability in mind, the disconnect circuit can operate stably even in harsh operating environments, effectively improving the stability and reliability of the entire system.

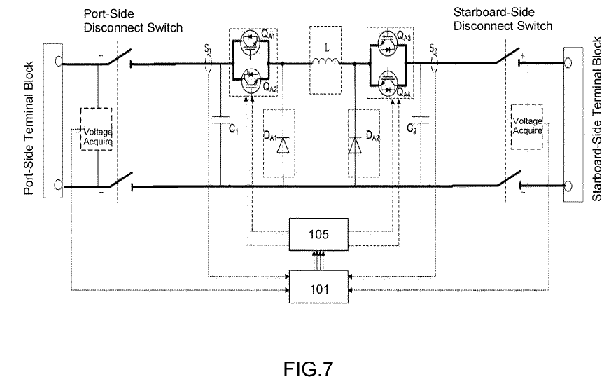

FIG. 7 is a schematic diagram of the structure of another marine DC solid-state circuit breaker arrangement according to embodiment of the present application. In addition to FIG. 4 to FIG. 6, the marine DC solid-state circuit breaker arrangement further comprises a freewheeling circuit. The freewheeling circuit specifically comprises a first freewheeling circuit and a second freewheeling circuit. The first freewheeling circuit comprises a port power diode D_{A1} and a first capacitor C1. The cathode of the port power diode D_{A1} is connected to the output of the port switch, the anode of the port power diode D_{A1} is connected to the negative electrode of the port circuit 1041, and the first capacitor C1 is connected in parallel between the positive and negative electrodes of the port circuit 1041. The second freewheeling circuit comprises a starboard power diode D_{A2} and a second capacitor C2. The cathode of the starboard power diode D_{A2} is connected to the output of the starboard switch, the anode of the starboard power diode D_{A2} is connected to the negative electrode of the starboard circuit 1042, and the second capacitor C2 is connected in parallel between the positive and negative electrodes of the starboard circuit 1042.

In order to absorb the energy when the main switch 103 is turned off, power diodes D_{A1} and D_{A2} are connected in parallel inside the main switch 103 to establish a freewheeling loop for the energy of the bus circuit. This allows the current to be commutated through this branch, reducing the voltage stress generated by Q_{A1} to Q_{A4} due to turning off the main switch 103, thereby ensuring the safety, speed and reliability of circuit disconnection.

Furthermore, with continued reference to FIG. 7, the marine DC solid-state circuit breaker arrangement further comprises a current-limiting reactor L which is connected between the port switch 1031 and the starboard switch 1032.

The port switch and the first freewheeling circuit form a buck (step-down) circuit, while the starboard switch and the second freewheeling circuit form another buck circuit. These two buck circuits are connected in anti-series to the marine DC solid-state circuit breaker arrangement, effectively improving the DC bus voltage regulation capability. Working together, the two buck circuits enable more precise current diversion and voltage regulation during fault conditions, ensuring that load-side equipment is not damaged by transient current surges.

Specifically, in the event of a short-circuit fault, the main switch structure described above can rapidly control the current rise rate and reduce the stress caused by the short-circuit current on equipment. The Buck circuit, with its efficient step-down conversion characteristics, not only reduces energy loss but also further improves current transmission efficiency through anti-series connection. The two anti-series Buck circuits effectively control each other during current transmission, ensuring that the short-circuit current does not rise too quickly and reducing voltage shocks to equipment (such as switching elements and power electronics). Furthermore, the anti-series Buck circuits can better regulate the DC bus voltage, ensuring that voltage fluctuations remain within acceptable limits. Even during load changes or short-circuit faults, the system voltage remains stable, effectively protecting load equipment and preventing system instability or equipment damage caused by voltage anomalies.

At the same time, the two Buck circuits in the anti-series configuration can effectively isolate the load. When a system fault occurs, precise current control can be used to isolate the fault current to a minimum, preventing the fault from spreading to other devices and improving the system's fault tolerance and reliability.

Buck circuits, as solid-state switches, avoid the mechanical wear and tear of traditional bus tie switches, resulting in a longer service life and higher reliability. The absence of arcing ensures stable operation of the electrical system even under high-frequency use.

Continuing with the marine DC solid-state circuit breaker arrangement shown in FIG. 7, the two signal acquisition modules 102 comprise a port signal acquisition module and a starboard signal acquisition module. The controller 101 is configured to compare the port electrical signal acquired by the port signal acquisition module and the starboard electrical signal acquired by the starboard signal acquisition module with the normal electrical signal, and control the port switch to be disconnected and/or the starboard switch to be disconnected when the fault location is determined.

Furthermore, the busbar circuit is equipped with port and starboard disconnectors. These disconnectors connect and disconnect the circuit, maintaining a consistent timing logic with the solid-state main switch. This further ensures that faulty circuits are disconnected, improving the reliability of the busbar circuit system.

To enhance the busbar circuit's protective effect, the circuit breaker arrangement detects electrical signals from both the port and starboard circuits. Combined with high-speed sampling, calculation, and comparison judgment by the controller hardware and processor, the circuit breaker arrangement sets a suitable protection threshold. When the electrical signal exceeds the protection threshold, a fault is detected in either the port or starboard circuit, and the faulty circuit is disconnected. Furthermore, the parameters of the current-limiting reactor and capacitor are carefully designed so that the main circuit short-circuit current rises rapidly on the short-circuit side, allowing the current sensor to quickly detect the short-circuit current. On the IGBT-off side, the current rises slowly (relative to the short-circuit), allowing the controller hardware to quickly disconnect the faulty IGBT and reduce the current during IGBT shutdown. This significantly improves fault detection and fault circuit disconnection time, while ensuring busbar circuit safety, thereby enhancing circuit breaker efficiency.

For DC power supply systems, such as those used in marine DC power systems, a short circuit in any area can affect power supply to other healthy areas if it cannot be quickly shut off. To ensure power supply continuity and reliability, short-circuit detection and fault determination require a response time of tens of microseconds, with no failure or malfunction.

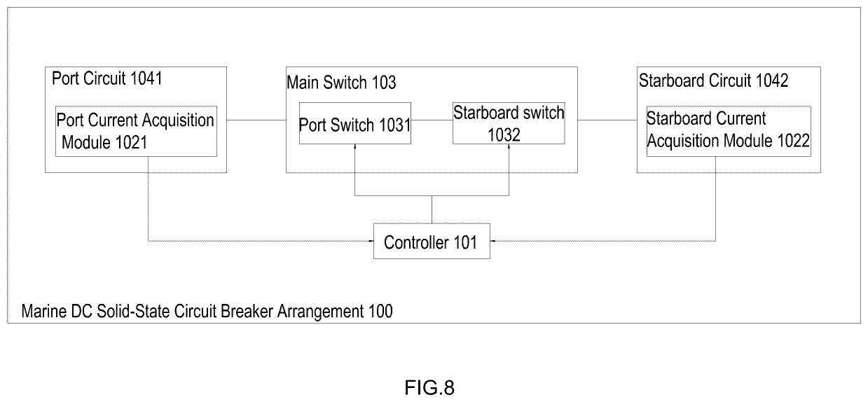

To further shorten the detection time of a faulty circuit, FIG. 8 is a schematic structural diagram of t the two signal acquisition modules according to an embodiment of the present application, wherein the two signal acquisition modules 102 comprise a port current acquisition module 1021 and a starboard current acquisition module 1022. Accordingly, the port electrical signal is the port current, and the starboard electrical signal is the starboard current. Based on the signal acquisition module shown in FIG. 8, the controller 101 can determine the fault location in the bus circuit based on the current signal and perform corresponding control.

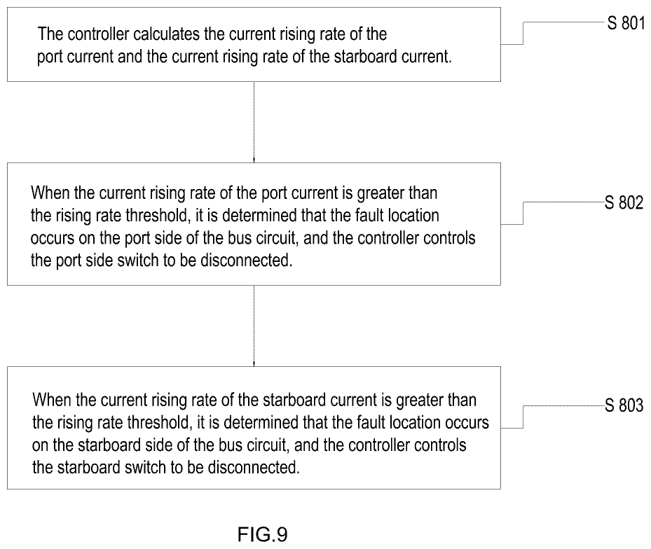

In some examples, the control process of the controller 101 may comprise the following steps as shown in FIG. 9.

S801: The controller calculates the current rising rate of the port current and the current rising rate of the starboard current;

S802: When the current rising rate of the port current is greater than the rising rate threshold, it is determined that the fault location occurs on the port side of the bus circuit, and the controller controls the port side switch to be disconnected;

S803: When the current rising rate of the starboard current is greater than the rising rate threshold, it is determined that the fault location occurs on the starboard side of the bus circuit, and the controller controls the starboard switch to be disconnected.

The current rise rate is a physical quantity that describes the speed of current change, representing the amount of current change per unit time. In electrical equipment and systems, the current rise rate is of vital importance, significantly impacting the safety and stability of the equipment. If the current rises too quickly, in some cases, such as in thyristors, it can cause localized overheating and damage the equipment. Therefore, real-time detection of the current rise rate is crucial to ensuring the safe and stable operation of electrical equipment and systems. Specifically, the current rise rate can be calculated by measuring the current change and the time interval. For example, the current rise rate can be calculated by dividing the current change by the time interval.

In other examples, the control process of the controller 101 may comprise, when it is determined that the current amplitude of the port current is greater than a current threshold, determining that the fault location occurs on the port side of the bus circuit, and the controller controlling the port switch to disconnect; when it is determined that the current amplitude of the starboard current is greater than the current threshold, determining that the fault location occurs on the starboard side of the bus circuit, and the controller controlling the starboard switch to disconnect.

In some other examples, the control process of the controller 101 can also adopt a dual judgment rule, that is, while judging the current rise rate, it also judges the current amplitude. By monitoring the current rise rate and amplitude in real time, the system can quickly determine the type and severity of the short circuit. The current rise rate can reflect the speed at which the short circuit occurs, and the amplitude can provide information on the intensity of the short-circuit current. Combining these two parameters, the type and nature of the short-circuit event can be more accurately determined, thereby avoiding the misjudgment and delay that may be caused by the traditional single judgment method.

Conventional protection systems can misjudge when current peaks reach a certain threshold, leading to untimely circuit breaker activation or over-protection. However, by combining both the rate of rise and the amplitude for dual determination, false trips caused by current fluctuations can be effectively prevented, ensuring the system responds accurately to short circuits. Furthermore, the system can quickly detect current changes as soon as the short-circuit current begins to rise, determining whether protective measures are necessary. By using the short-circuit rise rate, the system can very quickly identify short-circuit faults with high rise rates, reducing protection delays.

Real-time monitoring of the short-circuit rise rate allows the system to react as the current begins to rise, preventing failure to operate due to delays in detection before the short-circuit current reaches its limit. Through accurate detection, the system can promptly disconnect the fault circuit and prevent the fault from spreading.

In some examples, the signal acquisition module is a Rogowski coil. Rogowski coils provide high-precision current waveform capture and fast response, enabling accurate measurement of high-frequency signals and sudden currents. They are particularly suitable for rapidly changing currents, such as short-circuit current detection. Furthermore, Rogowski coils can accurately capture the current waveform during capacitor discharge, enabling timely identification of its impact on the system, helping to further improve the response speed and accuracy of short-circuit protection.

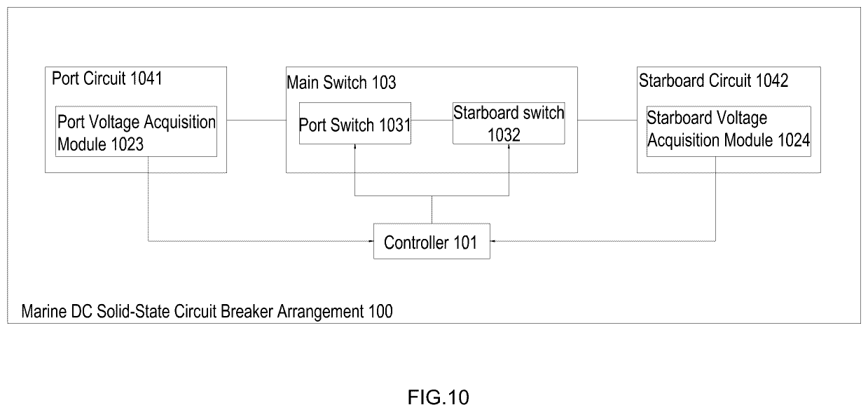

FIG. 10 is a schematic diagram of the structure of another signal acquisition modules according to an alternative mode of the above embodiment of the present application, wherein the two signal acquisition modules 102 comprise a port voltage acquisition module 1023 and a starboard voltage acquisition module 1024. Based on this, the port electrical signal is the port voltage, and the starboard electrical signal is the starboard voltage. Based on the signal acquisition module shown in FIG. 8, the controller 101 can control the port switch and the starboard switch to be disconnected when it is determined that the difference between the port voltage and the starboard voltage is greater than a voltage difference threshold.

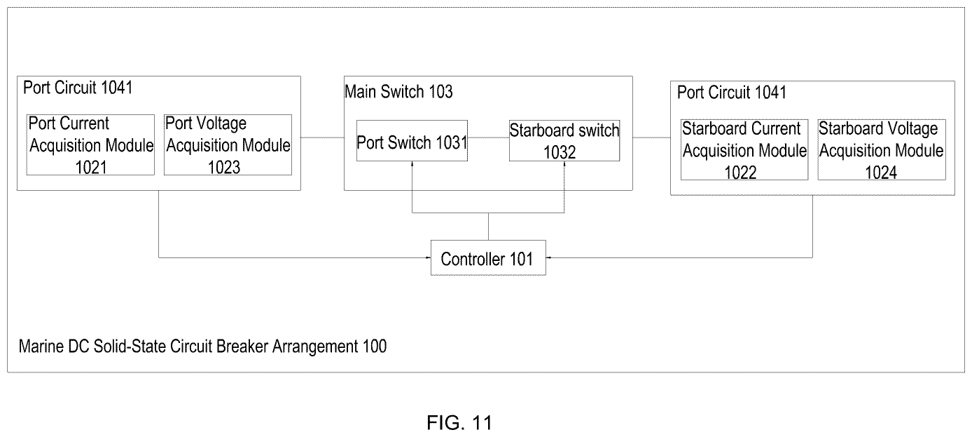

In order to more reasonably judge the fault type and fault location in the bus circuit, the signal acquisition module can include a current acquisition module and a voltage acquisition module at the same time. As shown in FIG. 11, the signal acquisition module simultaneously collects current signals and voltage signals and transmits them to the controller. The controller calculates and compares and judges, and uses the judgment conditions such as the current exceeding the current threshold and the voltage difference between the two ends being higher than the voltage difference threshold as the basis for fault protection. At the same time, the parameters of the current limiting inductor and capacitor are reasonably designed so that the short-circuit current rise rate of the main circuit rises rapidly on the short-circuit side, and the short-circuit current is quickly detected by the current sensor; while the circuit on the IGBT shutdown side rises slowly (relative to the short circuit), and cooperates with the controller hardware to quickly cut off the IGBT and reduce the current when the IGBT is turned off.

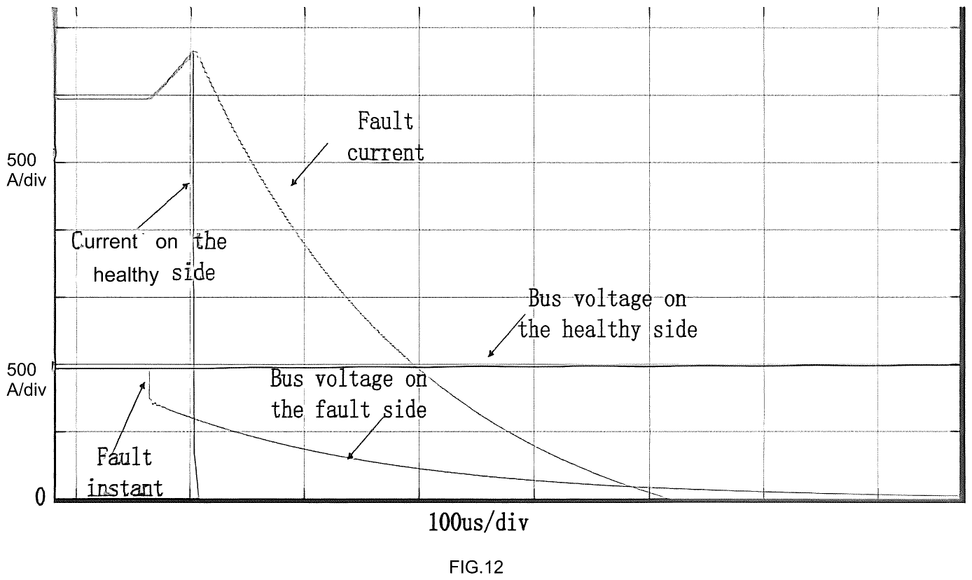

As shown in FIG. 12, it is a short-circuit protection simulation diagram. The short-circuit rise rate of the system shown in FIG. 11 is relatively fast (greater than 60 A/us), and the short-circuit current rise rate needs to be limited; the energy stored in the line inductance needs to be reasonably dissipated to protect the power electronic devices from overvoltage damage.

The marine DC solid-state circuit breaker arrangement according to the embodiments of this application uses hardware circuitry to detect the main circuit current. When the protection threshold is reached, a trip signal is output with a delay of 2-3 μs. The judgment value is transmitted to the controller (FPGA) with a delay of less than 1 μs. Upon receiving the trigger signal, the FPGA immediately executes the trip command with a delay of 2-3 μs. Upon receiving the trip command, the IGBT driver board executes the trip action and shuts down the IGBT in less than 10 μs. In summary, the entire process meets the 20 μs cutoff time requirement. This meets the requirement for rapid fault detection within a short period of time, improving the reliability of the entire circuit system.

While the basic principles of the present invention have been described above in conjunction with specific embodiments, it should be noted that the advantages, strengths, and effects mentioned herein are merely illustrative and non-restrictive, and should not be construed as necessarily possessed by each embodiment of the present invention. Furthermore, the specific details disclosed above are provided for illustrative purposes and to facilitate understanding, and are not intended to be limiting. These details do not necessarily limit the present invention to being implemented using these specific details.

The block diagrams of the devices, apparatuses, equipment, and systems involved in the present invention are intended to be illustrative examples only and are not intended to require or imply that they must be connected, arranged, or configured in the manner shown in the block diagrams. As will be appreciated by those skilled in the art, these devices, apparatuses, equipment, and systems may be connected, arranged, or configured in any manner. Words such as “include,” “comprise,” “have,” and the like are open-ended words that mean “including but not limited to,” and may be used interchangeably therewith. The words “or,” “and,” and “as used herein refer to the words “and/or,” and may be used interchangeably therewith, unless the context clearly indicates otherwise. The word “such as,” as used herein, refers to the phrase “such as, but not limited to,” and may be used interchangeably therewith.

It should also be noted that in the apparatus, device and method of the present invention, each component or each step can be decomposed and/or recombined, and such decomposition and/or recombination should be regarded as equivalent solutions of the present invention.

The above description of the disclosed aspects is provided to enable any person skilled in the art to make or use the present invention. Various modifications to these aspects will be readily apparent to those skilled in the art, and the general principles defined herein may be applied to other aspects without departing from the scope of the present invention. Therefore, the present invention is not intended to be limited to the aspects shown herein, but rather to be accorded the widest scope consistent with the principles and novel features disclosed herein.

The above description has been provided for the purpose of illustration and description. Furthermore, this description is not intended to limit the embodiments of the present invention to the forms disclosed herein. Although a number of example aspects and embodiments have been discussed above, those skilled in the art will recognize certain variations, modifications, alterations, additions, and sub-combinations thereof.

What is claimed is:

1. A marine DC solid-state circuit breaker arrangement, comprising:
a controller;
two signal acquisition modules;
a main switch; and
a bus circuit comprising a port circuit and a starboard circuit, wherein the main switch comprises a port switch and a starboard switch, wherein an output end of the port switch is connected to an output end of the starboard switch, an input end of the port switch is connected to the port circuit, and an input end of the starboard switch is connected to the starboard circuit;
wherein the two signal acquisition modules are connected to the bus circuit and are used to detect electrical signals in the bus circuit and send the electrical signals to the controller;
wherein one end of the controller is connected to the main switch and the other end thereof is connected to the two signal acquisition modules, the controller determines a fault location in the bus circuit based on the electrical signals sent by the two signal acquisition modules, and controls the port switch and the starboard switch to close and open according to the fault location;
wherein the marine DC solid-state circuit breaker arrangement further comprises a first freewheeling circuit and a second freewheeling circuit, wherein the port switch and the first freewheeling circuit, together with the starboard switch and the second freewheeling circuit, form two buck circuits connected in the marine DC solid-state circuit breaker arrangement in an anti-series manner;
wherein the two signal acquisition modules comprise a port signal acquisition module and a starboard signal acquisition module, the controller is configured to compare a port electrical signal acquired by the port signal acquisition module and a starboard electrical signal acquired by the starboard signal acquisition module with a normal electrical signal, and control the port switch to be disconnected and/or the starboard switch to be disconnected when the fault location is determined;
wherein the port electrical signal is a port current, and the starboard electrical signal is a starboard current;
wherein the first freewheeling circuit comprises a first power diode and a first capacitor, a cathode of the first power diode is connected to the output end of the port switch, an anode of the first power diode is connected to a negative electrode of the port circuit, and the first capacitor is connected in parallel between positive and negative electrodes of the port circuit; wherein the second freewheeling circuit comprises a second power diode and a second capacitor, a cathode of the second power diode is connected to the output end of the starboard switch, an anode of the second power diode is connected to a negative electrode of the starboard circuit, and the second capacitor is connected in parallel between positive and negative electrodes of the starboard circuit.

2. The marine DC solid-state circuit breaker arrangement according to claim 1 wherein the port switch comprises a first IGBT module and a second IGBT module, a collector of the first IGBT module is connected to a collector of the second IGBT module and is connected to the bus circuit, and an emitter of the first IGBT module is connected to an emitter of the second IGBT module as the output end of the port switch; wherein the starboard switch comprises a third IGBT module and a fourth IGBT module, a collector of the third IGBT module is connected to a collector of the fourth IGBT module and is also connected to the bus circuit, an emitter of the third IGBT module is connected to an emitter of the fourth IGBT module as the output end of the starboard switch.

3. The marine DC solid-state circuit breaker arrangement according to claim 1 further comprising an IGBT driver board connected between the main switch and the controller to control the main switch according to a control instruction sent by the controller.

4. The marine DC solid-state circuit breaker arrangement according to claim 1 wherein the controller is configured to, when determining that a current rise rate of the port current is greater than a rise rate threshold, determine that the fault location occurs on a port side of the bus circuit, and control the port switch to disconnect; and, when determining that a current rise rate of the starboard current is greater than the rise rate threshold, determine that the fault location occurs on a starboard side of the bus circuit, and control the starboard switch to disconnect.

5. The marine DC solid-state circuit breaker arrangement according to claim 4 wherein the controller is further configured to, when determining that a current amplitude of the port current is greater than a current threshold, determine that the fault location occurs on the port side of the bus circuit, and the controller controls the port switch to disconnect; and, when determining that a current amplitude of the starboard current is greater than the current threshold, determine that the fault location occurs on the starboard side of the bus circuit, and the controller controls the starboard switch to disconnect.

6. The marine DC solid-state circuit breaker arrangement according to claim 1 wherein each of the two signal acquisition modules is a Rogowski coil.
